(19) United States
(12) Patent Application Publication
(10) Pub. No.: US 2009/0153229 A1
(43) Pub. Date: Jun. 18, 2009

(54) Method for Signal Transmission between Semiconductor Substrates, and Semiconductor Component Comprising Such Semiconductor Substrates

(76) Inventors: Andre Hanke, Strausberg (DE); Helmuth Hermann, Dresden (DE); Michael Dunkel, Dresden (DE)

Correspondence Address: SLATER & MATSIL, L.L.P., 17950 PRESTON ROAD, SUITE 1000, DALLAS, TX, 75252, US

(21) Appl. No.: 11/957,312

(22) Filed: Dec. 14, 2007

(51) Int. Cl. G11C 5/14; H01L 23/48

(52) U.S. Cl. 327/530; 257/664; 257/E23.01

(57) ABSTRACT

An AC voltage signal is transmitted between a semiconductor substrate and a further semiconductor substrate arranged on the first semiconductor substrate by means of an electromagnetic field through one of the two semiconductor substrates by virtue of each semiconductor substrate having a circuit element that serves for transmission. Both circuit elements are directly electrically decoupled.

### BACKGROUND

Methods for signal transmission to a semiconductor substrate and semiconductor components with which the signal transmission methods can be performed are provided. The performance of semiconductor components in which semiconductor substrates are stacked one on top of another or are arranged individually or as a stack on a carrier substrate is influenced, inter alia, by the technologies with which the signals are transmitted between the individual components of the semiconductor component. Thus, it is necessary to obtain short switching times or high clock rates and short signal rise times for the transmitted signals.

A further requirement made of such arrangements is low-loss transmission to the individual components and also high signal integrity reflecting the analog factors of the signal, such as, e.g., the pulse edges or noise and distortion values. At a clock frequency starting from approximately 1 GHz these features gain in importance since, in this frequency range, limitations in the functionality of a semiconductor component occur which are based on the influence of parasitic characteristic quantities, on the reflection of signals or signal coupling in, so-called crosstalk.

### BRIEF DESCRIPTION OF THE DRAWINGS

In the accompanying drawings:

FIG. 1 illustrates a semiconductor component, comprising two semiconductor substrates arranged on a carrier substrate, with circuit elements for inductive signal transmission;

FIG. 2 illustrates a stack arrangement of semiconductor substrates with circuit elements for inductive signal transmission;

FIG. 3 illustrates a further stack arrangement of semiconductor substrates with circuit elements for inductive signal transmission, which are arranged around common vias running through the stack arrangement;

FIG. 4 illustrates two stacked semiconductor substrates with circuit elements for capacitive signal transmission from the lower to the upper semiconductor substrate;

FIG. 5 illustrates three stacked semiconductor substrates with circuit elements for capacitive signal transmission from the lower to the two upper semiconductor substrates;

FIG. 6 illustrates an embodiment of a semiconductor component with two stacked semiconductor substrates, which comprise circuit elements for capacitive signal transmission;

FIG. 7 illustrates a further embodiment of a semiconductor component with two stacked semiconductor substrates and with circuit elements for capacitive signal transmission;

FIG. 8 illustrates a semiconductor substrate with a capacitive contact for direct electrical decoupling of a signal path running through the semiconductor substrate;

FIG. 9 illustrates a further embodiment of a semiconductor component with two stacked semiconductor substrates and with circuit elements for capacitive signal transmission;

FIG. 10 illustrates some optical paths within a stack of semiconductor substrates;

FIG. 11 illustrates some optical functional elements and vias of a semiconductor substrate;

FIG. 12 illustrates a detail from a stack with two semiconductor substrates on a die with a central optical transmitting and receiving system as stack base;

FIG. 13 illustrates a detail from a stack with two semiconductor substrates with in each case a redistribution layer and with a die as stack base; and

FIGS. 14a-14c illustrate some details from semiconductor components from semiconductor substrates with means for scattering and focusing the light of the optical signal.

### DETAILED DESCRIPTION OF ILLUSTRATIVE EMBODIMENTS

In the description below, the term semiconductor substrate denotes any structure composed of a semiconductor material in which active or passive circuit elements are formed, independently of the degree of fabrication of the semiconductor substrate. Consequently, this term should be understood to mean both already singulated dies and wafer-level semiconductor substrates that are still in the wafer assemblage.

With the signal transmission methods described and the semiconductor component used for this purpose, the contacting of semiconductor substrates of the semiconductor component among one another or to a carrier substrate which accommodates a semiconductor substrate or a stack of semiconductor substrates and serves for electrical and, if appropriate, also mechanical integration into external circuit elements can be realized without direct electrical connection, i.e., galvanically isolated, on the basis of an electromagnetic field, i.e., by electromagnetic propagation. It is thus possible to obtain the contacting of the individual components of the semiconductor component even at high clock frequencies with short signal propagation times, in low-loss fashion and with little interference and with high signal integrity.

Through configuration and dimensioning of the circuit elements which serve for signal transmission, it is possible to reduce or avoid any influencing of a signal by undesired signal interference from adjacent connections or by reflections at high frequencies or interference radiations, also as a result of external fields, and nevertheless to ensure fast signal transmissions right into the range of gigahertz and beyond it. The method described can be utilized both for functional semiconductor components and for memory elements.

In various embodiments of the semiconductor components, the circuit elements can serve for signal transmission between the semiconductor substrates within a semiconductor component and also from or to the carrier substrate or else for signal transmission directly through one or more semiconductor substrates.

The circuit elements required for the signal transmission according to various embodiments can be formed or integrated in the semiconductor substrate by the known methods. Depending on the type of transmission and transmission direction and the transmission path, the circuit elements can be arranged only on one of the sides or on both sides of the semiconductor substrate.

A very high geometrical and functional variability can be obtained by means of the possible embodiments of the optical circuit elements required for the signal transmission. The signal path can be led vertically, through individual semiconductor substrates or else through a stack. It can be laterally deformed and then continued vertically in offset fashion.

It is possible to stack functionally identical semiconductor substrates, e.g., memory elements, which are selectively or uniformly read and written to by means of a signal. It is likewise possible to implement a selective driving of functionally different semiconductor substrates by means of signal paths designed in correspondingly differentiated fashion.

In further embodiments of the method and of the semiconductor component, the directly electrically decoupled, i.e., galvanically isolated, signal transmission by means of an electromagnetic field can be combined starting from a defined interface with a direct electrical connection. Thus, e.g., a redistribution layer of a semiconductor substrate with metallic interconnects can produce the connection of areally distributed signal inputs and signal outputs to an integrated circuit.

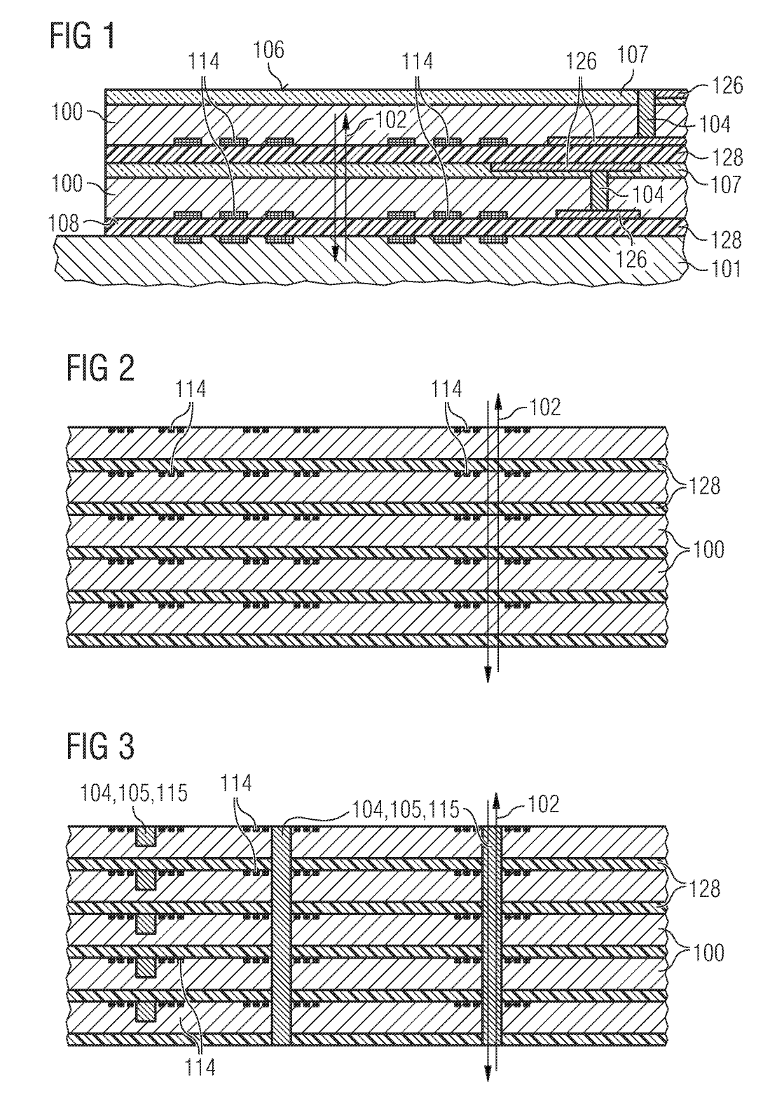

FIG. 1 illustrates a semiconductor component comprising two semiconductor substrates 100, here two dies, which are mechanically and electrically connected to a carrier substrate 101. The two semiconductor substrates 100 have an active region 107 on one side in each case, integrated circuits (not illustrated) being formed in the active region. That side of the semiconductor substrates 100 which encompasses the integrated circuit will be referred to hereinafter as front side 106, and the side opposite the front side 106 will be referred to hereinafter as rear side 108 of a semiconductor substrate.

Of the semiconductor substrates 100, the first is arranged face up on the carrier substrate 101 by means of a first die attach layer 128 and the second is likewise arranged face up on the first semiconductor substrate 100 by means of a second die attach layer 128. Both semiconductor substrates 100 are arranged with identical orientation in FIG. 1. In other embodiments, the semiconductor substrates 100 can be arranged face down or with mutually deviating orientation.

In its front side 106 and its rear side 108, the semiconductor substrates 100 have structured metallizations which produce lateral direct electrical connections as redistribution layer 126. In FIG. 1, a redistribution layer 126 of the front side 106 of a semiconductor substrate connects an electrically conductive filling 120 of a via 104 to a signal input or a signal output of the integrated circuit of the corresponding semiconductor substrate 100. A further redistribution layer 126 on the rear side 108 of the semiconductor substrate connects the filling 120 to a coil 114, which is formed on the rear side 108 in the form of a flat spiral and has a lateral extent. On account of its form, in the sectional illustration of FIG. 1, of the individual turns of the spiral, the cross sections thereof arranged alongside one another can be seen. A coil 114 having such a form will be referred to hereinafter as lateral coil.

The second semiconductor substrate 100 illustrated in FIG. 1 also has in each case a redistribution layer 126 on its front side 106 and its rear side 108, which are electrically connected by means of a via 104 with an electrically conductive filling 120. By means of the redistribution layer 126 of the rear side 108, the filling 120 and the redistribution layer 126 on its front side 106 of the semiconductor substrate 100, here as well a lateral coil 114 is electrically connected to a signal input or a signal output of the integrated circuit.

The carrier substrate 101 likewise has a lateral coil 114 in its surface facing the semiconductor substrates 100. The semiconductor substrates 100 are stacked one above another and on the carrier substrate in such a way that the three lateral coils 114 are in each case opposite one another with a spacing with respect to one another. In this case, the term “are opposite” should be understood to mean that a dielectric, e.g., air or at least one dielectric layer, is situated in the spacing between the coils 114, such that the two coils are directly electrically isolated. While the spacing between the coils 114 of the carrier substrate 101 and of the lower one of the two semiconductor substrates 100 is filled by the die attach layer 128, the lower semiconductor substrate 100 is furthermore situated between the two opposite coils 114 of the semiconductor substrates 100.

The signal transmission in a semiconductor component 100 in accordance with FIG. 1 is effected inductively and thus in potential-free fashion by means of an electromagnetic field that builds up around the coils 114. In this case, electromagnetic fields should be understood to mean any field which comprises both an electrical and a magnetic field component. During the inductive signal transmission, a current in a first of two mutually opposite coils 114 on account of an alternating magnetic field component acts on the electric circuit of the second coil 114. The two coils are connected to one another by means of a common magnetic flux. A consequence of this is that a change in the current of a coil 114, e.g., on account of an AC current present, leads to a change in the magnetic flux to the second coil 114 and thus to the induction of a voltage in the second coil 114. In this case, the efficiency of the inductive coupling of the two coils rises as the thickness of the semiconductor substrate 100 and of the die attach layer 128 decreases.

In this embodiment of the method for signal transmission, the coils 114 represent the circuit elements of the semiconductor substrate 100 which directly form a signal input or signal output of the integrated circuit of the semiconductor substrate 100 or are coupled to the latter or which serve merely for conducting the signal through the semiconductor substrate 100. In a further embodiment (not illustrated) of the method, a direct electrical decoupling within a semiconductor substrate 100 is also possible, e.g., by virtue of the semiconductor substrate 100 comprising two coils which are arranged one above another and which are separated by a dielectric layer. The dielectric layer can be formed, e.g., by an oxide of the semiconductor.

A small lateral offset of two inductively coupled coils 114, as illustrated in FIG. 1 on the basis of the example of the two coils 114 of the semiconductor substrates 100, is noncritical on account of the direct electrical decoupling and on account of the inductive signal transmission to the extent that the offset does not lead to a change in the signal to be transmitted or to the influencing of an adjacent signal path 102 or of an adjacent other electronic element of the semiconductor substrate 100.

FIG. 2 illustrates a detail from a stack of semiconductor substrates 100 which match in terms of the arrangement of the coils 114 and are stacked one above another with identical orientation. In this case, the fact of whether the coils 114 are formed on the front side 106 or the rear side 108 of the semiconductor substrates can be disregarded since, in both configurations, the signal transmission is in each case effected through a semiconductor substrate 100. For the sake of better clarity, the active regions 107 and the redistribution layer 126 of the semiconductor substrates 100 are not illustrated in specific detail in FIG. 2. The semiconductor substrates 100 can in this case be both individual dies and stacked wafers in which the components of the dies have already been formed. The same applies to the illustration in FIG. 3. Here, too, a concrete degree of fabrication of the semiconductor substrates 100 is not illustrated in specific detail since the product and the method can be applied to semiconductor substrates 100 in various fabrication stages.

Depending, e.g., on the thickness of the semiconductor substrates 100 or the signal to be transmitted, in a further embodiment at least two coils 114 which realize a signal transmission are arranged around at least two vias 104 lying one above another, the vias being referred to hereinafter as via sequence 105. Due to directly electrically decoupling of the semiconductor substrates 100, it is understood that the vias 104 can be through vias or blind vias. The vias 104 of the through via sequence 105 are filled with a common magnetic core 115 and the vias 104 of the blind via sequence 105 are filled with separate magnetic cores 115 (FIG. 3), such that the inductive coupling is amplified on account of the increase in the magnetic flux density. Furthermore, the influence of the magnetic field on adjacent electronic elements of the semiconductor substrate 100 can be limited in this embodiment. For the configuration of the magnetic core 115 and the material thereof, the configurations known to the person skilled in the art are possible in accordance with the type and magnitude of the signal and further possible influencing variables.

Since the inductive signal transmission is independent of direction, it enables a bidirectional signal flow in each of the embodiments described. FIGS. 1 to 3 schematically illustrate the directions of the signal paths 102 which can be realized.

The inductive signal transmission can serve both for coupling the supply voltage into an individual semiconductor substrate 100 or into a stack arrangement of semiconductor substrates 100 and for coupling functional signals in or out. By way of example, in a stack of identical memory elements, all the elements can be driven in parallel. Die selection is likewise possible in a functional stack arrangement by means of a signal fed in inductively. In a further embodiment, inductive together with direct electrical signal coupling in and signal coupling out are combined, e.g., for the direct electrical transmission of low-frequency signals.

In an embodiment of a semiconductor substrate 100 with which the inductive signal transmission can be realized, the semiconductor substrate 100 comprises a plurality of coils 114 in an array arrangement, comparable to a BGA arrangement, such that a simultaneous signal transmission can be effected in each coil 114. Such signal transmission can be used both in logic and memory components for potential-free signal transmission and in sensor elements. It can likewise be effected from a carrier substrate 101 to a semiconductor substrate 100 or between two semiconductor substrates 100. In the former case, too, the semiconductor substrate 100 can be a component of a stack arrangement.

In a further embodiment, a semiconductor substrate 100 with an array arrangement of coils 114 is used as an areal sensor element by virtue of change in time of a location-dependent magnetic field being detected simultaneously and in location-dependent fashion by means of the signal induced in the individual coils 114. The location-dependent temporal change in a magnetic field can thus also be detected with a sensor element of this type. In a further embodiment, the coils 114 can have a magnetic core 115 in order to amplify the induction and hence the signal coupling in.

It goes without saying that other configurations of coils can also be used instead of the coil forms having a lateral extent that are illustrated in FIG. 1 to 3. By way of example, depending on the transmission parameters or on the scaling of the semiconductor substrates, the coils can be formed within a via at the wall thereof.

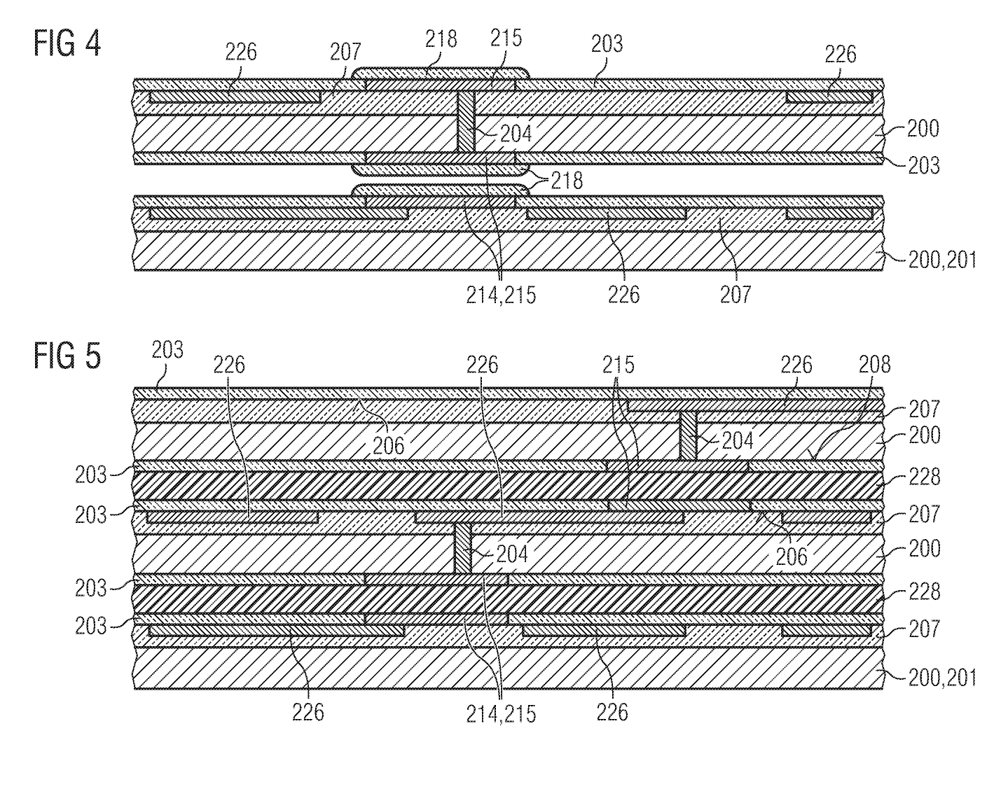

FIG. 4 shows a detail from a semiconductor component with two semiconductor substrates 200, in which the signal transmission between the two semiconductor substrates 200 is effected capacitively. In order to form the capacitive contact between the two semiconductor substrates, which for differentiation for further embodiments will be referred to as outer capacitive contact 214, each of the two semiconductor substrates 200 has an electrode 215 having a defined extent on the surface facing the respective other semiconductor substrate 200. The two semiconductor substrates 200 are arranged with a spacing with respect to one another, such that the two electrodes 215 are opposite one another with a spacing. The spacing can be produced by spacers (not specifically illustrated). The two electrodes 215 are covered with a thin dielectric layer 218, which simultaneously serves as a protective layer for the respective electrode.

A wide variety of materials which known for using as dielectric of a capacitor. Only silica shall be mentioned here as an example of a dielectric layer 218. As is known, the thickness of the dielectric and at the same time or alternatively the areas of the electrodes 215 can be reduced if use is made of dielectric materials having a high dielectric constant k, e.g., polyimide, which has a higher dielectric constant k than silicon dioxide.

The shape of the electrodes 215 can be diverse, and essentially depends on the space available on the semiconductor substrate 200. That is to say that alongside symmetrical forms, the areas can also assume an irregular shape as long as the capacitive signal transmission is ensured. On account of the usually higher structure density on the front side of a semiconductor substrate 200 in comparison with the rear side, the form of the electrodes will mainly depend on the integration capabilities there.

In a further embodiment, the electrodes 215 can also be integrated into the metallizations which can be applied on the front side and possibly also on the rear side of a semiconductor substrate 200 in order to form a redistribution layer 226. In FIG. 4, both semiconductor substrates 200 have in each case a redistribution layer 226 on their front side, in which the active region 207 having an integrated circuit is identified schematically. By means of the redistribution layer 226, an electrode 215 is connected to an integrated circuit or, e.g., to a further contact. The latter can also be, in one embodiment, a direct electrical or inductive contact.

In the upper one of the two semiconductor substrates 200 arranged one above another, in which one of the above-described electrodes 215 of the outer capacitive contact 214 is arranged on the rear side of the semiconductor substrate 200, a via 204 adjoins the contact. The via 204 has an electrically conductive filling 220 and thus produces a direct electrical contact between the electrode 215 on the rear side of the semiconductor substrate 200 and a further electrode 215 on the front side of the substrate. The further electrode 215 is formed over the active region 207 of the semiconductor substrate 200 and is covered with a dielectric layer. The further electrode 215 is thus able to make contact with a further semiconductor substrate 200 (not illustrated) capacitively.

It is evident that both the method of capacitive coupling and the configuration of a capacitive contact are independent of whether the transmission is effected between a carrier substrate and a semiconductor substrate or between two semiconductor substrates. Therefore, in the embodiment in accordance with FIG. 4, a carrier substrate can also be used instead of a semiconductor substrate 200, which is illustrated by the identification of the lower substrate. For this reason, the transmission partner of a semiconductor substrate will also hereinafter be referred to generally as substrate if a statement relates both to a carrier substrate and to a semiconductor substrate.

FIG. 5 illustrates a detail from a further embodiment, comprising two semiconductor substrates 200 and a substrate 200, 201, i.e., two semiconductor substrates 200 and a carrier substrate 201 or three semiconductor substrates 200. In this configuration, too, the substrates 200, 201 have a redistribution layer that laterally deforms the signal inputs and signal outputs of the integrated circuits. It is thus possible to arrange the position of the electrodes 215 of the capacitive contacts on the active side where space permits. The substrates 200, 201 in FIG. 5 have a passivation 203 at least on their front side and are all stacked one above another uniformly with their active region 207 upward, i.e., face up, and are connected to one another by means of a die attach layer 228. By means of the die attach layer 228, a spacing is set between two adjacent substrates 200, 201.

The three substrates 200, 201 are coupled to one another by two outer capacitive contacts 214 and a direct electrical connection between these contacts 214. The direct electrical connection is realized by means of a metallically filled via 205 and also the redistribution layer 226 of the middle semiconductor substrate 200. In a further embodiment instead of the direct electrical connection by filled via 204, a direct electrical decoupling of the upper semiconductor substrate 200 and the lower substrate 200, 201 can be formed in the middle semiconductor substrate 200 by means of an inner capacitive contact described below. Each of the two outer capacitive contacts 214 between in each case two substrates 200, 201 are formed by a first electrode 215 on the front side of the lower one of the two substrates 200, 201 and a second electrode 215 on the rear side of the upper one of the substrates. The dielectric between the electrodes 215 is formed by the die attached layer, which, for this purpose, need not be composed of a so-called low-k material, i.e., a material with a small dielectric constant relative to silicon dioxide. In this embodiment, the die attached layer replaces the above-described dielectric layer 218 with which an electrode is covered.

The upper capacitive contact 214 formed between the front side of the middle semiconductor substrate 200 and the rear side of the topmost semiconductor substrate 200 is connected to the integrated circuit of the topmost semiconductor substrate 200 by means of a metallically filled via 204 and the redistribution layer 226 of the semiconductor substrate. Consequently, the integrated circuits of the three substrates 200, 201 are connected to one another by means of the capacitive coupling in accordance with FIG. 5, such that they can be driven simultaneously if that is necessary. Since the capacitive coupling does not prefer any direction for signal transmission, the driving is furthermore also possible in bidirectional fashion.

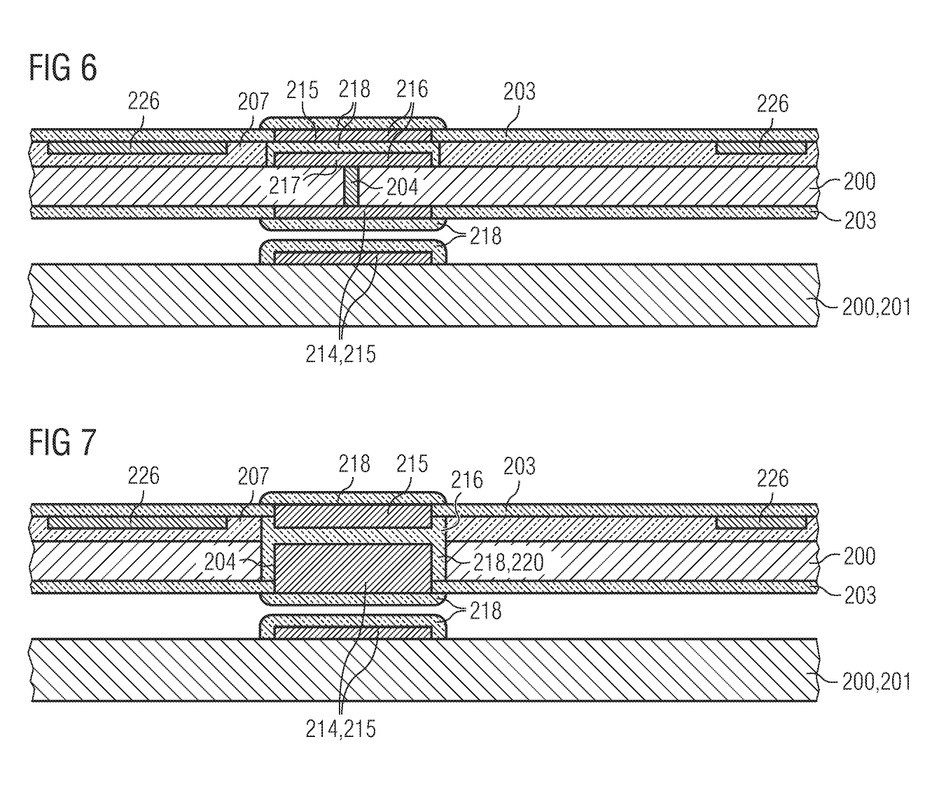

FIG. 6 illustrates a further embodiment of a semiconductor component with capacitive coupling, in which the signal transmission is effected from a carrier substrate 201 to a semiconductor substrate 200. It goes without saying that in this embodiment, too, instead of the carrier substrate a further semiconductor substrate can be coupled to the upper semiconductor substrate, e.g., if both semiconductor substrates are components of a stack. For this reason, here as well, as later in the description of FIG. 7, the lower component part will generally be referred to as a substrate.

For the sake of better clarity, with regard to the active region and the redistribution layer, the upper semiconductor substrate 200 is illustrated in a manner comparable to the semiconductor substrates 200 in FIGS. 4 and 5, but can also have a configuration that deviates from this.

The outer capacitive contact 214 between the two components is once again formed by two electrodes 215 which are covered with a dielectric layer 218 and have a defined spacing with respect to one another. The upper semiconductor substrate 200 likewise has a further electrode 215 on its front side, which further electrode can serve for forming a second outer capacitive contact.

In the embodiment illustrated, the two electrodes 215 on the front side and on the rear side of the upper semiconductor substrate 200 are connected electrically by means of an inner capacitive contact, but are directly electrically decoupled. For this purpose, a supplementary electrode 217 is formed in a cutout extending below the electrode 215 from the front side into the semiconductor substrate 200, the supplementary electrode having a spacing with respect to the electrode 215 and forming with the latter an inner capacitive contact. The supplementary electrode 217 is enveloped by a dielectric layer 218, such that the spacing with respect to the overlying electrode 215 is also filled by the dielectric. The supplementary electrode 217 is connected to the lower one of the two electrodes 215 of the semiconductor substrate 200 by an electrically conductively filled via 204.

An inner capacitive contact 216 is likewise realized in the embodiment in accordance with FIG. 7. In contrast to FIG. 6, here the two electrodes 215 of the upper semiconductor substrate 200 are arranged in a common via 204 made slightly larger than the two electrodes 215. The two electrodes are formed with a thickness such that their mutually opposite surfaces, in the interior of the via 204, have a spacing with respect to one another such that a capacitive coupling is possible. A dielectric filling 220 fills both the spacing between the electrodes 215 and the spacing of the electrodes 215 with respect to the wall of the via 204. Both spacings are dimensioned, inter alia, in accordance with the dielectric properties of the filling 220 and the electrical parameters of the signal to be transmitted and of the semiconductor component.

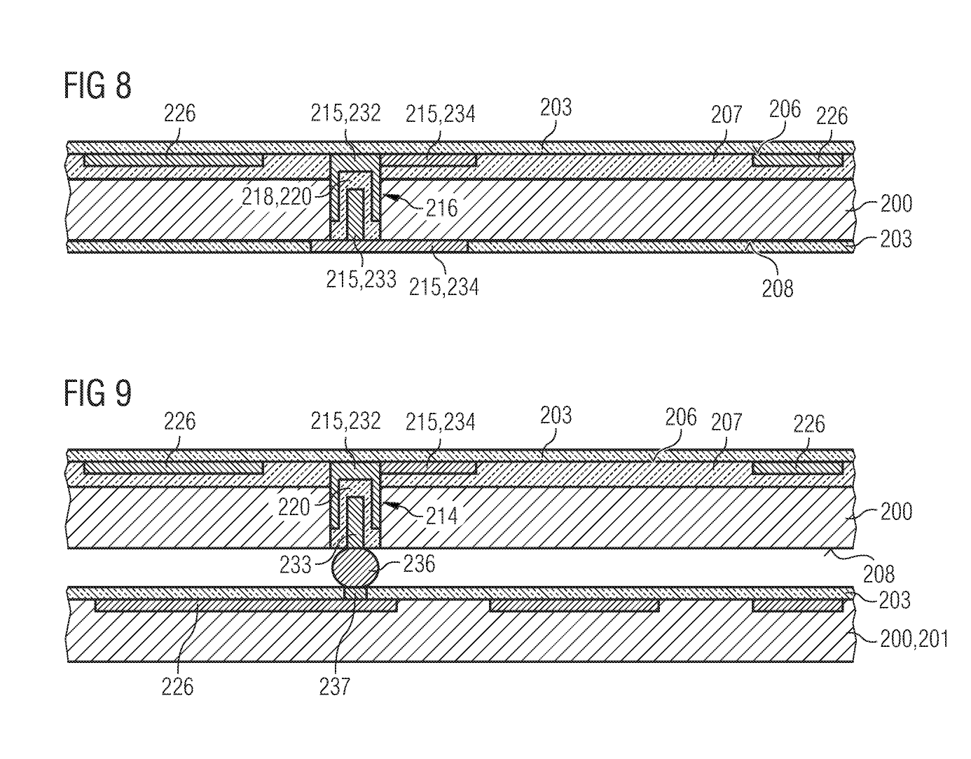

FIG. 8 shows a semiconductor substrate 200, which likewise has an inner capacitive contact 216 for direct electrical decoupling of the electrical connection of the two electrodes 215 on its front side and rear side. For this purpose, the two electrodes 215 have an areal extent 234 at the surface of the semiconductor substrate 200 and, in the interior of a via 204 in the semiconductor substrate 200, the forms of a socket 232 having an open end and of a pin 233 projecting into the socket. The pin 233 has, at all areas which are opposite the inner lateral surface of the socket 232, a spacing between pin 233 and socket 232 that is completely filled with a dielectric filling 220. The filling 220 also fills an interspace between the lower termination of the socket 232 and the areal extent 234. Consequently, the lateral surfaces of pin 233 and socket 232 form the electrode areas of the inner capacitive contact 216 and the areal extents 234 form the electrode areas for outer capacitive contacts 214. The semiconductor substrate 200 in accordance with FIG. 8 also comprises an integrated circuit in its active region 207, a redistribution layer 226 on its front side and also a passivation 203 on both sides.

FIG. 9 illustrates two semiconductor substrates 200 of a semiconductor component, which are coupled to one another by means of an outer capacitive contact 214 formed in a manner comparable to the contact illustrated in FIG. 8. The lower one of the two semiconductor substrates 200 can once again be both a carrier substrate and a semiconductor substrate, such that it is referred to hereinafter as substrate. It comprises a pin 233, which is directly electrically connected to the redistribution layer 226 by means of a solder ball 236 and the soldering pad 237 thereof. The redistribution layer 226 produces the connection to further contacts or to an integrated circuit (not illustrated) of the substrate 200, 201. The substrate is covered with a passivating protective layer 203.

The pin 233 projects into a socket which is formed in a via 204 of the upper semiconductor substrate 200 and the open end of which points toward the substrate. A spacing between the mutually opposite lateral surfaces of pin 233 and socket 232 is filled with a dielectric filling 220. At its closed end the socket 232 adjoins an areal extent 234 on the front side of the semiconductor substrate 200 which can serve as electrode for a further outer contact 214 with a further semiconductor substrate 200. As an alternative, the socket 232 can be connected to a redistribution layer 226 on the front side, which in turn realizes a connection to an integrated circuit in the active region 207 of the semiconductor substrate 200 or to a further contact (not illustrated). The further contact can be configured in a manner comparable to the outer contact 214 described or one of the alternative embodiments described above.

A further possibility for signal transmission by means of an electromagnetic field is optical signal transmission, in which the electromagnetic field issues from the source, a light transmitter, and propagates as an electromagnetic wave spatially. Optics generally encompasses light in the wavelength range which can be perceived by the human eye, and adjacent wavelength ranges whose propagation properties are similar to those of the visible spectral range. These include the infrared and the ultraviolet spectral range.

With optical signal transmission, in the same way as with inductive signal transmission, potential-free signal transmission is possible. The signal transmission is effected directly between a light transmitter and a light receiver or alternatively via a reflection element. At the interface between light transmitter or light receiver and the integrated circuit for which these elements serve as signal output or signal input, the electrical signals required for the function of the integrated circuits are available in accordance with their performance.

The optical functional elements, such as light transmitter, light receiver and reflection elements, which are to be used for the optical signal transmission can be integrated as separate components in the semiconductor component or can be formed directly in the semiconductor substrate. By producing a selected surface structure, planar or fissured, and also by means of a possible inclination or contour of the reflection area, it is additionally possible to establish in a targeted manner a portion of the light reflected in one direction and also an optical path. In connection with the configuration of the vias, by means of the ratio of reflected and transmitted radiation and by means of the ratio of reflection, scattering and focusing of the light, the optical signal required for contacting the respective semiconductor substrate can be set in accordance with the length and in accordance with the course of the optical path.

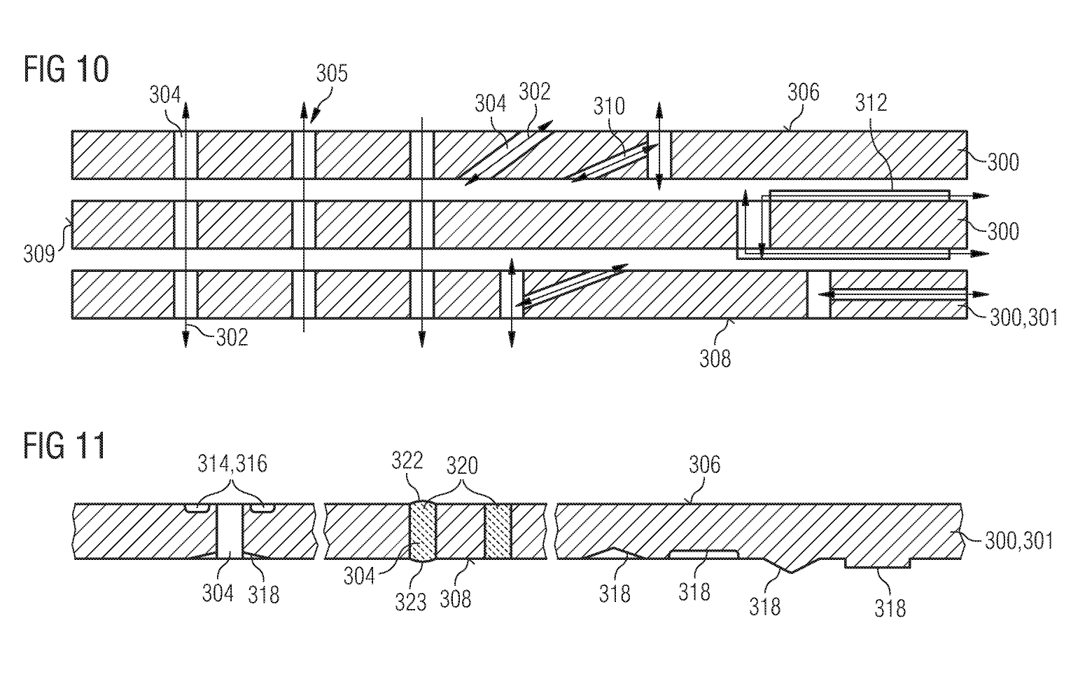

Possible optical paths 302 which run in a stack of semiconductor substrates 300 and by means of which optical signals can be transmitted to and from the semiconductor substrates 300 are illustrated in FIG. 10.

In the present description, a via 304 denotes any passage through the semiconductor substrate 300 which extends from the semiconductor substrate's front side 306 having active and passive circuit elements to the rear side 308 of the semiconductor substrate, wherein its direction can run both perpendicular to the front side 306 or rear side 308 and obliquely with respect thereto. This change of direction is possible in the optical signal transmission since the vias can be combined in a suitable manner by means of the optical functional elements not specifically illustrated in FIG. 10 in conjunction with scattering and focusing of the light. Accordingly, an optical path can also branch off from a via 304 by means of a passage 310 which proceeds from the via 304 or opens into the latter. The direction of such a branching-off passage 310 can also be varied. It can end both on the front side 306 and on the rear side 308 of the semiconductor substrate 300 or likewise on the peripheral lateral area 309 thereof. It is also possible to horizontally feed in or horizontally tap off optical signals laterally with respect to the semiconductor substrate 300, that is to say by way of the peripheral lateral areas 309 thereof. Here, too, as already described above, the signal transmission is possible both from a carrier substrate 301 and from a semiconductor substrate 300 to a further semiconductor substrate 300, or vice versa, such that a component of a semiconductor component that varies in this way will be referred to generally as substrate 300, 301.

Optical path 302 should be interpreted as the beam path of at least one portion of the light with which an optical signal is to be transmitted, passing from a light transmitter 314 to a light receiver 316 (FIG. 11). The fact that owing to scattering effects, diffuse reflection of other factors that spread the beam path, only part of the emitted light enters into the subsequent via 304 or the branching-off passage 310 or reaches the light receiver 316 can be disregarded since, through the possible combination of light scattering and focusing, the required portion to be received by the light receiver 316 can be set within sufficient limits.

The signal direction within a via 304, a via sequence 305, that is to say a plurality of successive vias of the stacked semiconductor substrates 300, or a passage 310 that branches off from a via 304 can be effected in accordance with the optical functional elements involved and the configuration thereof exclusively in one direction or along the same optical path 302 likewise in both directions if a temporal separation of outgoing and return signal can be realized, e.g., by means of a transmitting/receiving system.

The elements of a semiconductor substrate 300 which serve for the optical connection of this and the further semiconductor substrates 300 or carrier substrates 301, e.g., within a stack, are illustrated in FIG. 11. Light transmitter 314 or light receiver 316 or both are arranged on the front side 306 of a semiconductor substrate 300 and adjacent to a via 304, which can also be part of a via sequence 305. In this case, the light transmitter 314 represents an output and the light receiver 316 an input of an integrated circuit (not specifically illustrated) or of a circuit element (not specifically illustrated) of the semiconductor substrate 201. As already set out above, light transmitter 314 and light receiver can be connected to the circuit or a circuit element by means of a redistribution layer (not specifically illustrated).

At least one reflection element 318 is arranged on the rear side 308 of the semiconductor substrate 300. The reflection element 318 serves for changing the direction of the optical path, such that the latter is directed toward a semiconductor substrate of a stack that is opposite the reflection element and is not illustrated in FIG. 11, where it runs to or from a light transmitter 314, light receiver 316 or via 304. Consequently, the arrangement and the configuration of the reflection element 318 are to be adapted to the optical path to be produced. They can be arranged in distributed fashion in accordance with the impingement location of the light on the rear side 308 of the semiconductor substrate 300 alongside the via 304, directly adjacent to the latter or on the rear side 308 of the semiconductor substrate 300 and can be structured in accordance with the required reflection direction.

By means of an inclination of the reflection area relative to the rear side 308 of the semiconductor substrate 300, light emerging from a via 304, for example, can be reflected onto a region alongside the via 304 where light transmitter 314 or light receiver 316 or the input or output of an optical waveguide 312 or further passage 310 or via 304 is situated. In this case, the inclination can project into the rear side 308 or emerge from the latter. The reflection area can furthermore be offset into the semiconductor substrate 300 or project from the latter. In this way, e.g., the spacing with respect to an underlying substrate 300, 301 can be set in order to optimize the angular relations of the beam path of the light which arrives from there or is sent to there.

A further possibility for influencing the reflection consists in the configuration of the area of the reflection element 318 per se. On account of their band structure, semiconductors have a very good optical reflectivity, such that the semiconductor substrate 300 itself with one of the structurings represented above can serve as reflection element 318. Through suitable processing of the surface of the reflection element 318, a directional reflection can be effected at a smooth surface or a diffused reflection can be effected at a rough surface. Which of the two possibilities is applied depends essentially on the course of the optical path to be formed. The proportion of the reflected light is of secondary importance insofar as a radiation energy that reaches the value required for generating an electrical signal is to be received in a light receiver at the end of the optical path.

In the embodiment illustrated, the reflection elements 318 described are formed in the semiconductor substrate 300 itself since they can be produced cost-effectively by suitable processing methods. Given specific contours for optical properties which cannot be obtained, e.g., with the material of the semiconductor substrate 300, or for other reasons appertaining to production engineering, it is likewise possible for reflection elements 318 to be attached.

A further component for setting the course of the optical path is the via 304. The proportion of transmitted light can likewise be varied by means of the configuration of the via since scattering and focusing of the optical signal can likewise be set by means of reflections at the wall of the via 304 and by means of the filling thereof. With an unfilled via 304, the maximum transmission can be obtained either by means of a direct passage or by means of reflections at the wall, including multiple reflections. By means of filling 320, by contrast, the light can be focused or scattered.

A lens effect can be obtained by way of the selection of the material of the filling 320 with regard to the wavelength-dependent transmission and with regard to the refractive index in connection with the contour of the upper end 322 and lower end 323 of the filling 320. In the exemplary embodiment in accordance with FIG. 11, there is by way of example a biconvex lens having a convex contour of the upper end 322 and of the lower end 323 of the filling 320. With this configuration, as well as with modifications thereto, such as, e.g., a planoconvex or concavoconvex lens having greater curvature at the radiation output, it is possible to obtain focusing of the radiation. As is known, scattering is effected in the case of concave lenses (not specifically illustrated here) which can have at least one concave curvature at the two ends 322, 323 of the filling 320 and likewise in turn the abovementioned configurations of the curvatures.

Scattering of the light can also be obtained with a filling 320 of the via 304 which has the required transparency and has scattering particles or photoluminescent properties. Such a filling 320 can be applied in cases where, after the light has emerged from the via 304, a greater beam divergence is necessary in order to significantly change, e.g., the direction of the optical path. A further effect of a scattering or photoluminescent filling is a retardation of the signal, which can be avoided or used in a targeted manner.

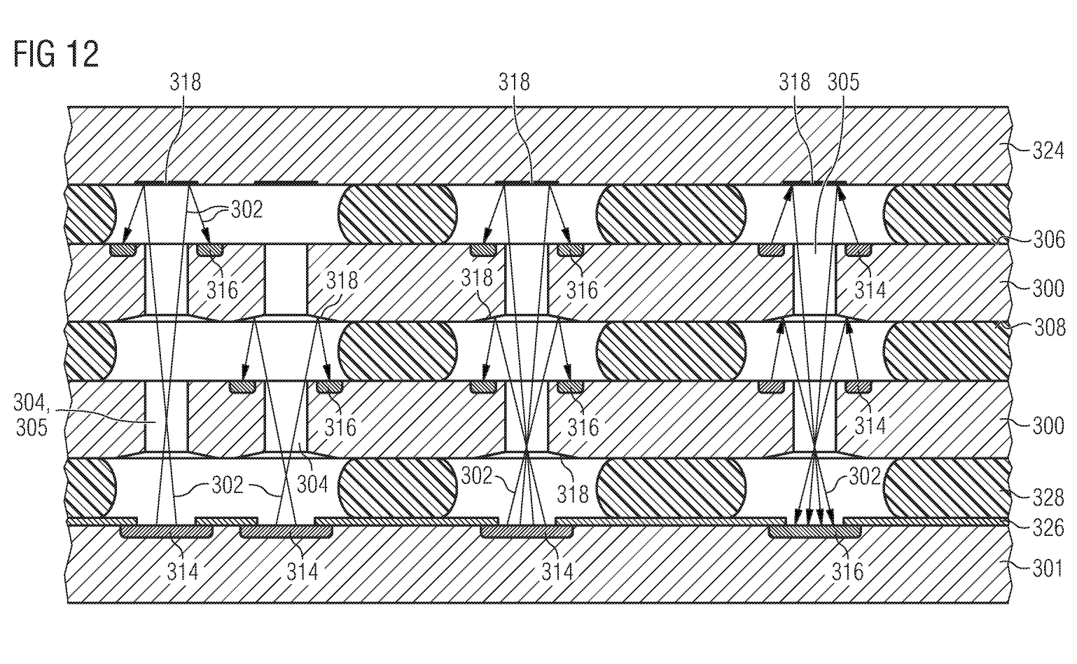

FIG. 12 illustrates the detail from a stack of semiconductor substrates 300 which comprises a carrier substrate 301 as carrier substrate, two semiconductor substrates 300 stacked thereon whilst maintaining a spacing, and a stack termination 324 stacked above the semiconductor substrates 300 once again whilst maintaining a spacing. Maintaining the spacing serves to create an optical path in order to direct the light by means of reflection onto a location that is spaced apart from the output of the via 304. This optical path and hence the location that can be reached by means of reflection in conjunction with minimization of the stack height can, e.g., also thereby be influenced in a targeted manner by virtue of the reflection element 318 being elevated or lowered relative to the surrounding surface.

In the exemplary embodiment, the spacing between the semiconductor substrates 300, the spacing between the bottommost semiconductor substrate 300 and the carrier substrate 301 and also between the topmost semiconductor substrate 300 and the stack termination 324 match. The spacings can likewise also deviate from one another. For example reasons appertaining to production engineering, reasons arising from the use of the stack or requirements of the optical path 302 may be present with regard to this.

In the exemplary embodiment in accordance with FIG. 12, the carrier substrate 301 is a semiconductor substrate in which light transmitters 314 as light emitting diode and light receivers 316 as photodiode are formed in the surface facing the stack. Light transmitters 314 and light receivers 316 are part of a central transmitting/receiving system which initiates the selection of the individual semiconductor substrates 300 and the driving of the selected semiconductor substrate 300. As an alternative, a printed circuit board that is usually used as a base for the mounting of semiconductor substrates 300 and has passive elements can also be equipped with the active elements, e.g., as SMD photodiodes or SMD light emitting diodes for optical coupling of the stack and serve as a stack base. In this embodiment of the semiconductor component according to the invention, the semiconductor substrates 300 of the stack can also be identical if this is permitted by the functionality of the semiconductor component.

The light transmitters 314 and light receivers 316 of the carrier substrate 301 are electrically contact-connected by means of a redistribution layer 326 in order to produce a connection to circuit elements (not specifically illustrated), e.g., those of a central transmitting and receiving system of the semiconductor component, or to contact locations for integrating the stack into an external circuit. Alongside making contact with the semiconductor substrates 300 of the stack and integration into an external circuit, the carrier substrate 301 can also serve for mechanically stabilizing the stack, e.g., very thin semiconductor substrates 300 are stacked.

The semiconductor substrates 300 are mechanically connected to one another and to the carrier substrate 301 by means of die attach layers 328, the spacing between the components being set by way of the thickness of the die attach layers 328. The die attach layer 328 is configured in such a way that the regions in which the optical path runs and in which the optical functional elements are formed are not covered by material.

The semiconductor substrates 300 of the semiconductor component have a plurality of vias 304 and adjacent to the vias 304 light transmitters 314 and light receivers 316 on the front side 306 and also reflection elements 318 on the rear side 308. The reflection elements 318 are in each case formed in the form of a phase which is arranged concentrically around each via 304 and is sunk by a few degrees into the rear side 308 of the via 304. With regard to the light transmitters 314 and light receivers 316, the semiconductor substrates 300 match only in the position thereof. Since, in the exemplary embodiments illustrated, the signal transfer is represented as monodirectional for the sake of better clarity, light receivers 316 or light transmitters 314 result depending on the direction of the signal transfer alongside the vias 304. If, as already set out above, the signals are temporally selected in accordance with their direction, e.g., by means of a circuit arrangement in the carrier substrate 301, it is possible to use the via sequences 305 or vias 304 for the bidirectional signal transfer by virtue of both light transmitters 314 and light receivers 316 being arranged at each via 304 and in the stack base 300 below the bottommost via 304.

The semiconductor substrates 300 of the semiconductor component in accordance with FIG. 12 are stacked in such a way that each via 304 is associated with a via sequence 305, such that a plurality of via sequences 305 are formed. Two of the via sequences 305 serve for the selection of the two semiconductor substrates 300. For this purpose, only the light receivers 316 of the semiconductor substrate 300 are active, i.e., connected to the circuit structure of the semiconductor substrate 300, which are arranged in the semiconductor substrate 300 to be selected. In order that the selection signal is not likewise communicated by means of an optical path 302 which, on account of the matching embodiment of the vias 304 and reflection elements 318, also runs to the second semiconductor substrate 300, which is not to be selected by means of the via sequence 305 under consideration, it is necessary to inactivate its light receivers 316. Instead of this it is also possible to stack semiconductor substrates 300 which differ in terms of the arrangement of the light receivers 316 alongside the vias 304 serving for selection. The inactive or alternatively obviated light receivers 306 are illustrated by dashed lines in FIG. 12.

In this case, the optical path 302 for selectively making contact with a semiconductor substrate 300 in the semiconductor component runs from a light transmitter 314 of the stack base 300 through an unfilled via 304 or through an unfilled via sequence 305, depending on the position of the semiconductor substrate 300 in the stack, as far as a reflection element 318 arranged in the overlying semiconductor substrate 300 or stack termination 324 in the beam path of the light passing through the via 304 or the via sequence 305. For the reflection of the light to a light receiver 316, the reflection element 318 has, relative to the bottommost semiconductor substrate 300 on account of its embodiment as a phase, an inclination relative to the surface of the semiconductor substrate 300, while the reflection element 318 of the stack termination 324 is a reflective area running essentially parallel to the surface of the semiconductor substrate 300. The differing inclination of the reflection elements 318 mentioned is based on the different angles of incidence of the light passing through the stack by way of paths of different lengths in conjunction with a constant diameter of the vias 304. As an alternative, the vias 304 can also concentrically narrow or widen as the stack height increases, depending on the stack height, beam path to be produced and the further measures for focusing or scattering the light in the course of the beam path.

The further via sequences 305 illustrated in FIG. 12 serve for reading and writing data to the selected semiconductor substrate 300. On account of the selection for the reading or writing operation, the optical paths 302, despite the direction, are formed identically for both cycles and for both semiconductor substrates 300. The direction is defined through the light transmitter 314 into the carrier substrate 301 and the light receivers 316 in the semiconductor substrates 300, or vice versa.

On account of the arrangement of light transmitter 314 and light receiver 316 in the vicinity of the via 304, it may be necessary for the light receiver 316 or the light transmitter 314 to be electrically connected to the integrated circuit by means of an interconnect (not specifically illustrated) of a redistribution layer.

In the exemplary embodiment in accordance with FIG. 12, the stack termination 324 is formed by a substrate composed of a semiconductor material which has no circuit elements. As a result, an adaptation of the stack materials and the thermal behavior thereof is effected and the reflection behavior is utilized for the formation of the reflection elements in this component. As an alternative, depending on the application of the semiconductor component, the stack termination 324 can also be composed of other material, e.g., a part of the housing to which the required reflection elements are attached, or a material having good heat-conducting properties which can serve for heat dissipation.

The stack illustrated in FIG. 12 comprises two active semiconductor substrates 300 alongside the stack termination 324. The number of semiconductor substrates 300 illustrated should not be interpreted as a restriction but rather as an example, since further semiconductor substrates 300 can be added to the stack in a comparable manner.

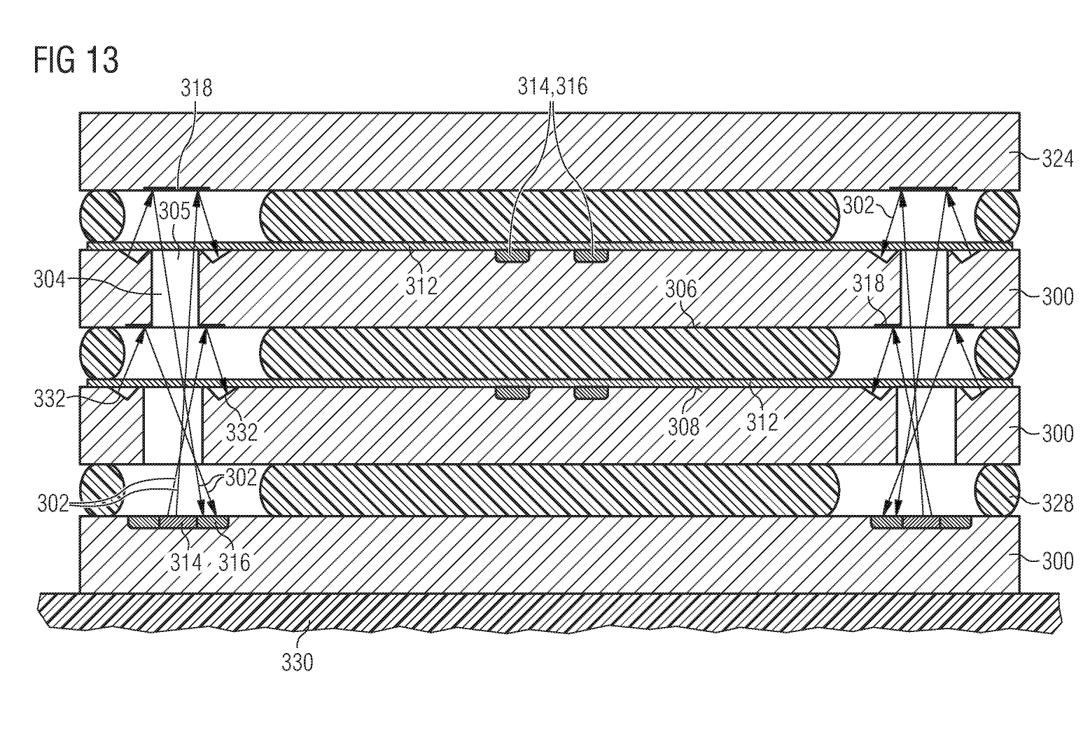

FIG. 13 illustrates a further embodiment with two semiconductor substrates 300 having double-row central row of light transmitters 314 and light receivers 316. With regard to the stacking of the individual semiconductor substrates 300 one on top of another and on the stack base 400 and also with regard to the stack termination, reference can be made to the explanations concerning FIG. 12.

The vias 304 of the individual semiconductor substrates 300 are situated principally in the edge regions thereof. Instead of light transmitters and light receivers which are arranged at the start or end of the optical paths 302 running through the via sequences 305, the central light transmitters 314 and light receivers 316 are optically connected by means of optical waveguides 312 to further reflection elements 332 arranged adjacent to the vias 304 on the front side 306 of the semiconductor substrates 300 in such a way that the light impinging there is reflected into the optical waveguide 312. Thus, an optical signal which emerges from the via sequence 305 is forwarded as far as the central light transmitters 314 and light receivers 316. Such a lateral delay of the signal is known as redistribution and serves, e.g., for shifting the connection contacts of an integrated circuit into regions where the coupling in or tapping off of signals is simpler to realize.

The optical path 302 between a light transmitter 314 or a light receiver 316 of a stack base, which can be both semiconductor substrate 300 and carrier substrate 301, and a further reflection element 332 once again runs, as explained above, through the vias 304 by way of a reflection element 318 on the rear side of a semiconductor substrate 300. In the exemplary embodiment, the reflection elements 318 are embodied at each semiconductor substrate 300 essentially parallel to the surface of the semiconductor substrate 300. In order nevertheless to obtain, upon direct passage through the via sequence 305 at each semiconductor substrate 300, the angle of the incident beam which is required for reflection to the further reflection element 332, the vias 304 of the lower semiconductor substrate 300 are concentrically enlarged.

The stack base, in the exemplary embodiment illustrated a semiconductor substrate mounted on a PCB (Printed Circuit Board), has, below each via sequence 305, light emitting diodes and photodiodes as light transmitters 314 and light receivers 316, which are formed concentrically with respect to one another and below each via sequence 305 in the semiconductor substrate 300. Each via sequence 305 can thus be utilized bidirectionally for optical contacting.

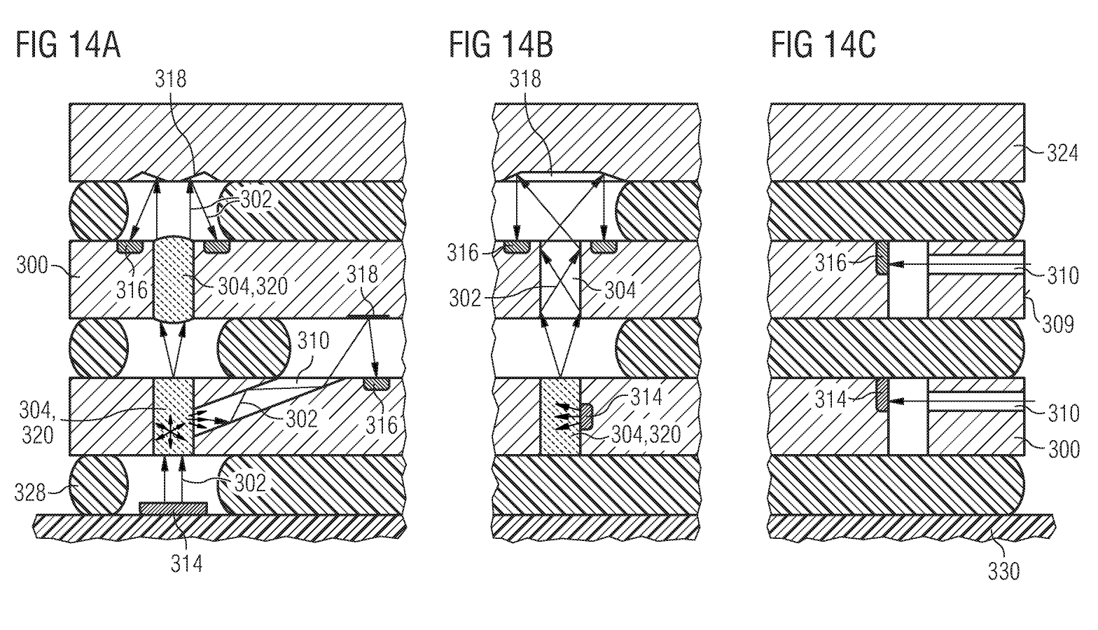

FIGS. 14a to 14c illustrate by way of example various optical paths 302 which can be produced alternatively or supplementarily also in the above-described embodiments for optical signal transmission if particular requirements are present or changes in direction in the optical path 302 prove to be necessary or expedient. In these illustrations, too, the stacking is of secondary importance, such that in this regard reference can be made to the explanations above.

The use of fillings 320 in the vias 304 for focusing and scattering the light and for realizing a branch junction is illustrated in FIG. 14a. The optical path 302 runs from an SMD light emitting diode, which is mounted on PCB 330 and functions as light transmitter 314, into the first via 304 of a via sequence 305. The via 304 has a filling 320 comprising scattering particles, such that the light is scattered diffusely within the via 304.

One part of the scattered light leads the via 304 upward in the direction of the via sequence 305 and another part enters into a branching-off passage 310, which begins in the lateral wall of the via 304 and, running obliquely upward, ends in the front side 306 of the semiconductor substrate 300. The branching-offpassage 310 is unfilled and its walls are smooth and highly reflective, such that a large proportion of the light passes through and impinges on the reflection element 318 of the semiconductor substrate 300 stacked thereabove, which is approximately opposite the output of the branching-off passage 310. The reflection element 318 is formed by the highly reflective rear side of the semiconductor substrate 300. From there the light is reflected to a light receiver 316 arranged alongside the output of the branching-off passage 310.

That part of the light which passes from the lower via 304 of the via sequence 305 into the interspace between the two semiconductor substrates 300 has a relatively high degree of scattering. In order to obtain focusing for the further course of the optical path 302 in this direction, the succeeding via 304 of the via sequence 305 is likewise filled and both ends 322, 323 of the filling 320 are embodied with a convex contour. Consequently, the light emerging from this via 304 forms an image of the via at infinity. By means of the inclination of the reflection elements 318 above this second via 304, the reflection takes place into the light receivers 316 alongside the via 314.

In a further example of a course of an optical path 302, a light transmitter 314 is formed in the wall of the lower via 304 of a via sequence 305 (FIG. 14b). The light emitted into the overlying half-space is diffusely scattered by the filling 320 of the via 304, the filling likewise having scattering particles, and enters diffusely into the interspace between the two semiconductor substrates 300 and into the overlying via 304. A comparable diffuse scattering in the lower via 304 can also be obtained by means of a rough surface of the wall. The second via 304 of the via sequence 305 has no filling and a smooth, highly reflective surface, such that the light impinges, after multiple reflection at the wall, on the reflection element 318 in the stack termination 324. The reflection areas thereof are once again inclined relative to the surrounding area, such that reflection takes place to the light receivers 316 alongside the upper via 304.

Alongside the course of the optical path 302 explained above, it is also possible for an optical signal to be coupled in or tapped off through the peripheral lateral area 309 of the semiconductor substrate by virtue of a branching-off passage 310 beginning there and opening into a via (FIG. 14c). Arranged approximately opposite the mouth of the opening is either a light transmitter 314 or a light receiver 316, which is connected to the circuit elements. As an alternative, the location of the light transmitter 314 or the light receiver 316 can also be the starting point of an optical path 302 which, with the use of scattering and reflection processes by means of suitable vias 304 and reflecting elements 318 and, if appropriate, also optical waveguides 312 as described above, runs to light transmitters 314 or light receivers 316 in the interior of the semiconductor component 300 and other semiconductor substrates 300.

It is shown clearly on the basis of the above-described configurations of the optical paths 302 that, by means of suitable combination of the configuration of the filling 320 of the vias 304 of a via sequence 305 composed of divergently scattering material, the configuration of the contour of the ends of the filling 320 and the configuration of the reflection elements 318 arranged alongside the vias 304 of the via sequences 305 at the output of each via 304 of the via sequence 305, it is possible to set a defined ratio of the reflected proportion of the light to the light emerging from the via 304. By way of example, the ratio can be such that the proportion of the reflected light becomes smaller toward the upper vias 304, and that of the transmitted light becomes larger.

The above-described examples of the embodiments represent an exemplary enumeration and not a restriction. The invention also includes further combinations of the claimed features which the person skilled in the art would implement on the basis of his expert knowledge.

The production of a semiconductor component or of a semiconductor substrate is effected by the known methods for producing integrated circuits, for introducing vias on a mechanical or chemical basis and for die bonding by means of adhesive-bonding technology. These technologies can be applied both to individual dies and to wafers on which the circuit elements are formed. If the via sequences are introduced after the stacking of the semiconductor substrates, it must be ensured through the corresponding adhesive application or the subsequent removal of the adhesive through the vias that the required regions mentioned above are free of adhesive.

What is claimed is:

1. A method for signal transmission between at least two stacked semiconductor substrates, the method comprising:
transmitting an AC voltage signal from a first circuit element to a second circuit element, the first circuit element being arranged on a first semiconductor substrate of the at least two stacked semiconductor substrates and the second circuit element being arranged on a second semiconductor substrate of the at least two stacked semiconductor substrates;
wherein transmitting the AC voltage signal includes transmitting the AC signal through at least one of the semiconductor substrates of the at least two stacked semiconductor substrates,
wherein transmitting the AC voltage signal includes transmitting the AC signal utilizing electromagnetic propagation by means of an electromagnetic field and in directly electrically decoupled fashion through one of the two semiconductor substrates.

2. The method for signal transmission as claimed in claim 1, wherein transmitting the AC voltage signal comprises transmitting the AC voltage signal from a first coil, which serves as a transformer turn and is arranged on an active side of the first semiconductor substrate, to a second coil, which serves as a transformer turn and is arranged on an active front side of the second semiconductor substrate, the transmitting occurring by means of induction through at least one of the semiconductor substrates.

3. The method for signal transmission as claimed in claim 2, wherein the at least two stacked semiconductor substrates are mounted on a carrier substrate, the method further comprising transmitting a second AC voltage signal from a further coil serving as a transformer turn on a surface of the carrier substrate into the first coil or the second coil, the second AC voltage signal being transmitted by inductive coupling.

4. The method for signal transmission as claimed in claim 2, further comprising transmitting an AC voltage signal from the second circuit element to the first circuit element such that the signal transmission is effected bi-directionally.

5. The method for signal transmission as claimed in claim 2, wherein the AC voltage signal is amplified by a magnetic core adjacent the first coil and/or second coil.

6. The method for signal transmission as claimed in claim 1, wherein transmitting the AC voltage signal comprises transmitting the AC voltage signal by capacitive coupling by means of a first capacitive contact of the first semiconductor substrate to a second capacitive contact of the second semiconductor substrate, the first and second capacitive contacts being separated from one another by a dielectric.

7. The method for signal transmission as claimed in claim 6, wherein the AC voltage signal fed into the second semiconductor substrate by means of capacitive coupling is forwarded directly electrically in the semiconductor substrate.

8. The method for signal transmission as claimed in claim 6, wherein the AC voltage signal fed into the second semiconductor substrate is forwarded within the second semiconductor substrate by means of capacitive coupling by means of a further, inner capacitive contact in the second semiconductor substrate.

9. The method for signal transmission as claimed in claim 6, further comprising transmitting the AC voltage signal by capacitive coupling by means of a further capacitive contact from a carrier substrate to one of first or second semiconductor substrates.

10. The method for signal transmission as claimed in claim 6, further comprising transmitting the AC voltage signal from the second semiconductor substrate to the first semiconductor substrate such that signal transmission is effected bidirectionally.

11. A semiconductor component comprising semiconductor substrates, comprising:
at least two semiconductor substrates stacked one on top of another and each having a front side in which an integrated circuit is formed, and a rear side opposite the front side; and
a circuit element on each of the semiconductor substrates for signal transmission from one circuit element to another by means of an electromagnetic field, wherein the two circuit elements are directly electrically decoupled.

12. The semiconductor component as claimed in claim 11, wherein the circuit elements comprise coils for inductive signal transmission from one semiconductor substrate to another, and wherein the semiconductor substrates are stacked one above another with identical orientation of the front and rear sides in such a way that adjacent coils are opposite one another with a semiconductor substrate lying in between.

13. The semiconductor component as claimed in claim 12, wherein the coils comprise lateral coils.

14. The semiconductor component as claimed in claim 13, wherein the lateral coils each are arranged concentrically around an opening of a via of the respective semiconductor substrate, and the vias of the semiconductor substrates lie one above another and are filled with a magnetic core.

15. The semiconductor component as claimed in claim 12, wherein the semiconductor substrates are arranged on a carrier substrate and the carrier substrate has a further coil, which is opposite the coil of the lower semiconductor substrate of the semiconductor component.

16. The semiconductor component as claimed in claim 15, wherein the two coils are opposite one another with the semiconductor substrate lying in between.

17. The semiconductor component as claimed in claim 12, wherein the semiconductor substrates each comprise a plurality of coils in mutually corresponding array arrangements.

18. A semiconductor component comprising:
at least two semiconductor substrates, each semiconductor substrate having a front side in which an integrated circuit is formed, and a rear side opposite the front side, and
a carrier substrate on which the semiconductor substrates are arranged, the carrier substrate having at least one first coil for inductive signal transmission to a lower one of the semiconductor substrates;
wherein at least one semiconductor substrate of the semiconductor component has a second coil for inductive signal transmission, and the semiconductor substrates are arranged on the carrier substrate in such a way that the two coils are opposite one another.

19. The semiconductor component as claimed in claim 18, wherein the two coils are opposite one another with at least one semiconductor substrate lying in between.

20. The semiconductor component as claimed in claim 18, wherein the lower semiconductor substrate and the carrier substrate each comprise a plurality of coils in mutually corresponding array arrangements.

21. The semiconductor component as claimed in claim 18, wherein the coils comprise lateral coils.

22. A semiconductor substrate for producing a semiconductor component with inductive signal transmission, the substrate comprising
a front side having an integrated circuit;
a rear side opposite the front side; and
a lateral coil arranged on at least one of the front side and/or the rear side.

23. The semiconductor substrate as claimed in claim 22, wherein the lateral coil is arranged concentrically around an opening of a via that extends from the front side to the rear side of the semiconductor substrate, the via being filled with a magnetic core.

24. The semiconductor substrate as claimed in claim 22, wherein the lateral coil is electrically connected to the integrated circuit.

25. The semiconductor substrate as claimed in claim 22, comprising a plurality of coils in an array arrangement, the lateral coil being one of the plurality of coils.

26. The use of a semiconductor substrate as claimed in claim 25, wherein temporal fluctuations of a magnetic field are detected in location-dependent fashion by means of the individual coils of the array arrangement.

27. A semiconductor component comprising:
a first semiconductor substrate having a front side and a rear side opposite the front side, an integrated circuit being disposed at the front side of the first semiconductor substrate;
a further substrate having a top side and an underside, the further substrate being connected to the first semiconductor substrate, wherein the first semiconductor substrate has a first electrode and the substrate has a second electrode arranged in such a way that the first and second electrodes are opposite one another with a space therebetween; and
a dielectric arranged in the space between the first and second electrodes, such that the first and second electrodes together with the dielectric form an outer capacitive contact for capacitive signal transmission between the substrate and the semiconductor substrate.

28. The semiconductor component as claimed in claim 27, wherein the semiconductor substrate comprises a further electrode for forming a further outer capacitive contact on the side opposite to the side having the first electrode, wherein the first electric and the further electrode are directly electrically connected.

29. The semiconductor component as claimed in claim 27, wherein the first and second electrodes have the form of a socket having a closed end, the socket being formed in a via in the semiconductor substrate, further comprising a pin projecting into the socket at an open end.

30. The semiconductor component as claimed in claim 27, wherein a semiconductor substrate comprises a further electrode for forming a further outer capacitive contact on the side that is opposite to the side having the first electrode, and wherein the first electrode and the second electrode are capacitively coupled.

31. The semiconductor component as claimed in claim 30, further comprising a further semiconductor substrate, wherein the semiconductor substrate and the further semiconductor substrate are capacitively coupled to one another by means of the further outer capacitive contact and an electrode of the further semiconductor substrate.

32. The semiconductor component as claimed in claim 27, wherein the first semiconductor substrate and the substrate each comprise a plurality of electrodes in mutually corresponding array arrangements, the electrodes forming an array of capacitive contacts.

33. A semiconductor substrate for producing a semiconductor component with capacitive signal transmission, the substrate comprising:
a front side having an integrated circuit;
a rear side opposite the front side; and
a first electrode on the front side of the semiconductor substrate; and
a second electrode on the rear side of the semiconductor substrate, wherein the electrodes are electrically connected to one another.

34. The semiconductor substrate as claimed in claim 33, wherein at least one of the first electrode and or the second electrode is electrically connected to the integrated circuit.

35. The semiconductor substrate as claimed in claim 33, wherein at least one of the first electrode and or the second electrode is covered with a dielectric layer.

36. The semiconductor substrate as claimed in claim 33, wherein the first electrode and the second electrode are directly electrically connected to one another by means of a via that extends from the first electrode to the second electrode, the via being filled with electrically conductive material.

37. The semiconductor substrate as claimed in claim 33, wherein the first electrode and the second electrode are directly electrically connected to one another by means of a via filled with electrically conductive material and by means of an interconnect that is adjacent to the via and runs on the front side or the rear side of the semiconductor substrate.

38. The semiconductor substrate as claimed in claim 33, wherein the first electrode and the second electrode are capacitively coupled to one another by means of an inner capacitive contact.

39. The semiconductor substrate as claimed in claim 38, wherein the inner capacitive contact comprises electrodes arranged in a common via in such a way that they are opposite one another and are separated from one another by a dielectric layer.

40. The semiconductor substrate as claimed in claim 38, wherein at least one of the electrodes of the inner capacitive contact is also an electrode of an outer capacitive contact.

41. The semiconductor substrate as claimed in claim 38, wherein at least one of the electrodes of the inner capacitive contact is arranged in a cutout that is introduced into the semiconductor substrate.

42. The semiconductor substrate as claimed in claim 38, wherein the electrodes of the inner capacitive contact comprise a socket having an open end and a closed end, the socket being formed in a via in the semiconductor substrate, a pin projecting into the socket at its open end.

43. The semiconductor substrate as claimed in claim 38, wherein one of the electrodes of the inner capacitive contact is directly electrically connected through the semiconductor substrate to a supplementary electrode, which is arranged in a cutout in the semiconductor substrate and is covered with a dielectric layer and forms a capacitor with another of the electrodes.

44. The semiconductor substrate as claimed in claim 33, wherein the dielectric material has a higher dielectric constant than silicon dioxide.
